(19) United States
(12) Patent Application Publication
(10) Pub. No.: US 2026/0110090 A1
(43) Pub. Date: Apr. 23, 2026

(54) GAS DISTRIBUTOR, GAS DELIVERY APPARATUS, AND FILM PROCESSING APPARATUS THEREOF

(71) Applicant: ADVANCED MICRO-FABRICATION EQUIPMENT INC. CHINA, Shanghai (CN)

(72) Inventors: Xuezi LI, Shanghai (CN); Ning ZHOU, Shanghai (CN); Yuejun GONG, Shanghai (CN); Can XU, Shanghai (CN)

(21) Appl. No.: 19/116,310

(22) PCT Filed: Aug. 30, 2023
(86) PCT No.: PCT/CN2023/115815

§ 371 Date: Mar. 27, 2025

(30) Foreign Application Priority Data
Oct. 10, 2022 (CN) 202211231507.9

(51) Int. Cl. C23C 16/455; C23C 16/44

(52) U.S. Cl. CPC C23C 16/4558; C23C 16/4408; C23C 16/45544; C23C 16/45565

(57) ABSTRACT

Disclosed in the present disclosure are a gas distributor, a gas delivery apparatus and a thin film processing apparatus. The gas distributor includes a first surface and a second surface arranged opposite to each other, a gas diffusion channel is arranged in the gas distributor, and the gas diffusion channel includes a recessed portion with a bottom surface protruding from the second surface, the recessed portion divides an area below the second surface into an inner area and an outer area, the recessed portion includes a first sidewall surrounding the inner area and a second sidewall surrounding the first sidewall, where the first sidewall comprises first gas channels, and the second sidewall comprises second gas channels, and gases in the gas diffusion channel enter the inner area and the outer area via the first gas channels and the second gas channels, respectively.

### CROSS-REFERENCE TO RELATED APPLICATIONS

This application is a national stage of International Application No. PCT/CN2023/115815, filed on Aug. 30, 2023, which claims priority to and the benefit of Chinese Patent Application No. 202211231507.9, filed on Oct. 10, 2022. Both of the aforementioned applications are hereby incorporated by reference in their entireties.

### TECHNICAL FIELD

The present disclosure relates to the field of semiconductor equipment, specifically to a gas distributor, a gas delivery apparatus, and a thin film processing apparatus.

### BACKGROUND

In the manufacturing process of semiconductor devices, a large number of micro-fabrication is required, with commonly used methods including atomic layer deposition (ALD), chemical vapor deposition (CVD), or plasma treatment processes that utilize the principle of a reaction chamber to process wafers. With the ongoing miniaturization of feature sizes and the increasing integration of semiconductor devices, the application of processes like atomic layer deposition and chemical vapor deposition has become increasingly widespread. Although thin film deposition apparatuses have undergone multiple upgrades with significant improvements in performance, there are still many deficiencies in terms of thin film deposition yield and production output. As chip technology continues to evolve and technology nodes progress, the demands for higher wafer processing quality and production output are becoming increasingly stringent.

For example, in some cases, wafer surfaces are treated with thin film deposition by the atomic layer deposition process. During the atomic layer deposition process, a precursor gas adsorbed on a wafer surface and reaction gases that react with the precursor gas are alternately delivered into a reaction chamber. An atomic layer of a reaction product is deposited on the wafer surface to form a thin film, where purge gases are also introduced between the supply of the precursor gas and the supply of the reaction gases to ensure the cleanliness of an internal environment of the reaction chamber. However, when using existing thin film deposition apparatuses to perform gas circulation, the flow rate and velocity of process gases delivered by central and peripheral areas of a shower head of a gas delivery apparatus typically differ. This results in poor uniformity of distribution of the process gases above the wafer, leading to undesirable phenomena such as uneven thickness, non-uniform composition, and inconsistent physical properties of the thin film deposited on the wafer surface, which in turn reduces the yield of wafer production. On the other hand, an existing gas delivery apparatus has limited throughput for the process gases. To ensure the quality of thin film growth, it is often necessary to introduce purge gas for an extended period to purge and clean the interior of the reaction chamber, thereby increasing the production time of wafer thin film and significantly affecting the overall wafer processing yield. Therefore, existing thin film processing apparatuses cannot meet the current production demands.

### SUMMARY

An objective of the present disclosure is to provide a gas distributor, a gas delivery apparatus and a thin film processing apparatus. The gas distributor is provided with a gas diffusion channel, where the gas diffusion channel comprises a recessed portion, the recessed portion comprises first gas channels and second gas channels that output process gases toward different directions/areas, the gas distributor delivers the process gases to different areas via the first gas channels and the second gas channels, achieving stable and rapid delivery of the process gases at a higher flow rate based on the principles of flow convection and diffusion, thereby achieving good distribution uniformity of the process gases in a short period, and helping to improve the yield rate and production yield of thin film deposition on wafers.

In order to achieve the above objective, the present disclosure is implemented through the following technical solutions:

A gas distributor, comprising a first surface and a second surface arranged opposite to each other, wherein a gas diffusion channel is arranged in the gas distributor, the gas diffusion channel comprises a recessed portion with a bottom surface protruding from the second surface, the recessed portion divides an area below the second surface into an inner area and an outer area, the recessed portion comprises a first sidewall and a second sidewall, where the first sidewall surrounds the inner area and comprises a plurality of first gas channels, and the second sidewall surrounds the first sidewall and comprises a plurality of second gas channels, and gases in the gas diffusion channel enter the inner area via the first gas channels and enter the outer area via the second gas channels.

In one embodiment, the first gas channels are through holes in a horizontal direction or through holes at an angle to the horizontal direction.

In one embodiment, the second gas channels are through holes in a horizontal direction or through holes at an angle to the horizontal direction.

In one embodiment, the height of the first gas channels is the same as or different from the height of the second gas channels.

In one embodiment, the number of the second gas channels is equal to or not equal to the number of the first gas channels;

and/or, the diameter of the second gas channel is equal to or not equal to the diameter of the first gas channel.

In one embodiment, the plurality of first gas channels are arranged uniformly or non-uniformly in a circumferential direction of the first sidewall of the recessed portion;

and/or, the plurality of second gas channels are arranged uniformly or non-uniformly in a circumferential direction of the second sidewall of the recessed portion.

In one embodiment, distances from outlet ends of at least two of the first gas channels to the second surface are the same or different.

and/or, distances from outlet ends of at least two of the second gas channels to the second surface are the same or different.

In one embodiment, a gas delivery apparatus comprises:

a cover plate provided with a gas delivery channel;

a gas distributor having the foregoing features and located below the cover plate, the gas delivery channel of the cover plate is in gas communication with the gas diffusion channel;

a shower head, located below the gas distributor and provided with a plurality of gas through-holes;

an upper surface of the shower head and the inner area below the gas distributor form a central gas diffusion area, and the upper surface of the shower head and the outer area below the gas distributor form a peripheral gas diffusion area, gases in both the central gas diffusion area and the peripheral gas diffusion area flow out through the gas through-holes on the shower head below.

In one embodiment, the gas diffusion channel is an annular gas diffusion channel formed on the gas distributor, and the annular gas diffusion channel divides the first surface into a first central area surface and a first peripheral area surface.

In one embodiment, the annular gas diffusion channel is a continuous annular channel or a plurality of discontinuous arc-shaped segment channels.

In one embodiment, a cross-section of the annular gas diffusion channel is square and/or rectangular and/or inverted-T-shaped.

In one embodiment, the height of the first central area surface is lower than the height of the first peripheral area surface.

In one embodiment, the height of the first central area surface is equal to or higher than the height of the first peripheral area surface.

In one embodiment, a carrying member is provided between the cover plate and the shower head, and the carrying member is used to carry the gas distributor.

In one embodiment, the position of the gas distributor carried by the carrying member is adjustable.

In one embodiment, a bottom surface of the cover plate is a planar structure, and when the height of the first central area surface is lower than the height of the first peripheral area surface, the bottom surface of the cover plate makes contact with the first peripheral area surface, a first gap is formed between the bottom surface of the cover plate and the first central area surface, and the gases are delivered via the gas delivery channel to the gas diffusion channel within the first gap.

In one embodiment, a bottom of the cover plate comprises a single-step structure, a horizontal step surface of the single-step structure makes contact with the first peripheral area surface, a first gap is formed between the horizontal step surface of the single-step structure and the first central area surface, and the gases are delivered via the gas delivery channel to the gas diffusion channel within the first gap.

In one embodiment, the bottom of the cover plate comprises a two-step structure, the circumference of a sidewall of a first step of the two-step structure is smaller than the circumference of a sidewall of a second step, a horizontal surface of the first step makes contact with the first peripheral area surface, a first gap is formed between the horizontal surface of the first step and the first central area surface, and the gases are delivered via the gas delivery channel to the gas diffusion channel within the first gap.

In one embodiment, the height of a portion of the second surface that is located in the outer area is the same as or different from the height of the horizontal surface of the second step.

In one embodiment, the distance of the first gap is greater than 1 mm.

In one embodiment, the distance from the first sidewall of the recessed portion to the central axis of the gas distributor is 10% to 80% of the radius of the gas distributor.

In one embodiment, the distance from the first sidewall of the recessed portion to the central axis of the gas distributor is 20% to 70% of the radius of the gas distributor.

In one embodiment, the distance between the bottom surface of the recessed portion protruding from the second surface and the shower head is greater than or equal to 0.

In one embodiment, the distance between the bottom surface of the recessed portion protruding from the second surface and the shower head is greater than or equal to 1 mm.

In one embodiment, a bottom of the gas delivery channel is a cone frustum opening structure, and the circumference of an inner sidewall at a top of the cone frustum opening structure is smaller than the circumference of an inner sidewall at a bottom thereof.

In one embodiment, the cover plate is connected to the gas distributor through a mechanical fastening apparatus;

and/or, the shower head is connected to the cover plate through a mechanical fastening apparatus.

In one embodiment, materials for the preparation of the cover plate and/or the gas distributor and/or the shower head comprise aluminum.

In one embodiment, a thin film processing apparatus comprises:

a reaction chamber, comprising a top cover and a chamber body;

the gas delivery apparatus, the gas delivery apparatus is connected to the top cover and used to deliver the process gas into the interior of the reaction chamber.

In one embodiment, the gas delivery apparatus is used to alternately deliver reaction gas and purge gas into the interior of the reaction chamber in a cyclic manner.

In one embodiment, the reaction gas comprise a first reaction gas and a second reaction gas, and in one circulation process, the time required for the first reaction gas, the purge gas, the second reaction gas and the purge gas is less than or equal to 2 s.

In one embodiment, the thin film processing apparatus is an atomic layer deposition process apparatus.

In one embodiment, the top cover and the cover plate are integrally formed.

In one embodiment, the gas distributor is detachably connected to the top cover.

Compared with the prior art, the present disclosure has the following advantages:

the present disclosure provides a gas distributor, a gas delivery apparatus and a thin film processing apparatus; the gas distributor is provided with the gas diffusion channel, the gas diffusion channel comprises the recessed portion, and the recessed portion comprises the first gas channels and the second gas channels that output the process gases toward different directions/areas; based on the principles of flow convection and diffusion, the process gases delivered through the gas distributor achieve a more uniform distribution, thereby ensuring a more uniform distribution of the process gases delivered onto a wafer surface, guaranteeing the quality of thin film deposition on wafers and helping improve the yield rate of wafer production; at the same time, the process gases can still maintain a high flow rate during the delivery through the gas distributor, which not only ensures distribution uniformity of the process gases but also increases the throughput of the process gases within a short period, thereby helping to improve the production yield of wafers.

### BRIEF DESCRIPTION OF THE DRAWINGS

FIG. 1 shows a schematic view of a thin film processing apparatus according to the present disclosure;

FIG. 2 shows a cross-sectional schematic view of a three-dimensional structure of a gas delivery apparatus according to the present disclosure;

FIG. 3 shows a structural schematic view of the gas delivery apparatus according to the present disclosure;

FIG. 4 shows a partial enlarged schematic view of the gas delivery apparatus according to the present disclosure;

FIG. 5 shows a schematic view of a three-dimensional structure of a gas distributor according to the present disclosure;

FIG. 6 shows a front view of the gas distributor according to the present disclosure; and

FIG. 7 shows a bottom view of the gas distributor according to the present disclosure.

### DETAILED DESCRIPTION OF EMBODIMENTS

In order to make objectives, technical solutions and advantages of the embodiments of the present disclosure clearer, the technical solutions in the embodiments of the present disclosure will be clearly and completely described below in conjunction with the drawings of the embodiments of the present disclosure. Obviously, the described embodiments are part of, but not all of, the embodiments of the present disclosure. Based on the embodiments of the present disclosure, all other embodiments obtained by those of ordinary skill in the art without creative efforts shall fall within the scope of protection of the present disclosure.

It should be noted that the terms “comprising”, “including”, “having”, or any other variant thereof herein are intended to cover non-exclusive inclusions, such that a process, method, article or terminal device that includes a series of elements not only includes those elements, but also includes other elements not explicitly listed, or also includes elements inherent to such process, method, article or terminal device. Without further limitations, an element defined by the phrase “including.” or “comprising.” does not exclude the presence of additional elements in the process, method, article, or terminal device that includes the mentioned elements.

It is to be noted that the accompanying drawings in a quite simplified form with an inaccurate ratio are merely used to assist in describing the objectives of the embodiments of the present disclosure conveniently and clearly.

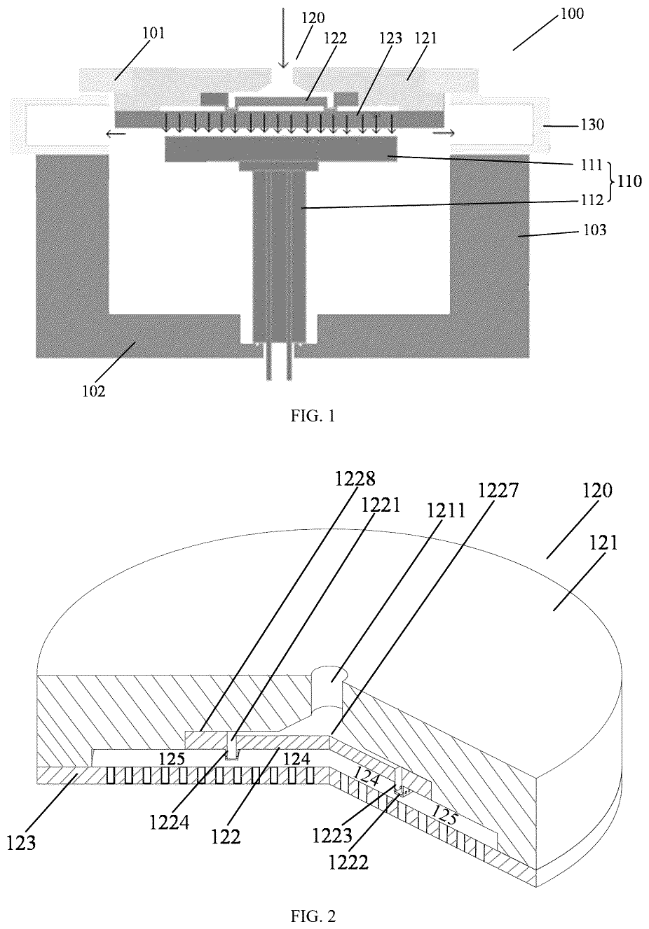

FIG. 1 shows a schematic view of a thin film processing apparatus according to the present disclosure, where the apparatus includes a reaction chamber 100, the reaction chamber 100 is used to process one or more wafers, including depositing a material on an upper surface of the wafer or within recessed features of the wafer. The reaction chamber 100 is surrounded by a top cover 101 at a top end, a bottom wall 102 at a bottom end, and a sidewall 103 between the top cover 101 and the bottom wall 102. The bottom wall 102 and the sidewall 103 form a chamber body portion of the reaction chamber 100. A base 110 is arranged inside the reaction chamber 100. The base 110 includes a wafer carrier 111, a base table, and an extension tube 112 extending downward. A top of the wafer carrier 111 is a carrying surface for carrying the wafer. The base 110 can be switched between at least two upper and lower positions to meet the requirements for the process and wafer switching procedures.

As shown in FIG. 1, the reaction chamber 100 is further provided with a gas delivery apparatus 120 and an emission port. The gas delivery apparatus 120 is located at a top of the reaction chamber 100 and connected to the top cover 101. The gas delivery apparatus 120 is connected to a gas supply apparatus (not shown in the figure). The emission port is formed in a gas flow guide assembly 130, which is located between the top cover 101 and the sidewall 103. The emission port formed in the gas flow guide assembly 130 is distributed along a circumferential direction. A gas pumping apparatus emits gas within the reaction chamber 100, namely a reaction waste product, out of the chamber through the emission port. During the process (directions of arrows in FIG. 1 indicating a flow direction of process gas), the process gas within the gas supply apparatus are delivered to the interior of the reaction chamber 100 via the gas delivery apparatus 120. Thin film deposition processes or purging are carried out in a wafer processing area above the wafer to ensure the smooth progression of the thin film deposition process. The subsequent process gases are emitted from the chamber body through the emission port.

In one embodiment, the process gases include one or more reaction gases (e.g., a precursor gas like TiCl₄, reactive gas like NH₃) and purge gases (like N₂). These various gases can be alternately delivered into the interior of the reaction chamber 100. In this embodiment, the thin film processing apparatus is an Atomic Layer Deposition (ALD) process apparatus. The gas delivery apparatus 120 is used to alternately deliver the reaction gases and purge gases into the interior of the reaction chamber 100 in a cyclic manner. As an example, in a typical atomic layer deposition process for TiN growth, TiCl₄/N₂/NH₃/N₂ gases are sequentially introduced into the reaction chamber to complete the following growth cycle: 1) TiCl₄ is delivered to a wafer and adsorbed onto a surface of the wafer; 2) N₂ purges gaseous TiCl₄ from a gas line, the shower head, and a process gap above the wafer; 3) NH₃ flows into the reaction chamber and reacts with the adsorbed TiCl₄(s) on the wafer surface to form a monolayer of TiN thin film; and 4) N₂ removes NH₃ and other gaseous substances. The above cycle is repeated until the TiN thin film grows to a desired thickness. Through the aforementioned atomic layer deposition process, a high-quality TiN thin film can be grown and obtained. It is understandable that the thin film processing apparatus of the present disclosure is not limited to the aforementioned atomic layer deposition process apparatus and may also be a thin film processing apparatus for implementing other types of processes. The present disclosure imposes no restrictions in this regard. Similarly, the types of process gases are not limited to those described above.

It should be noted that the thin film processing apparatus does not necessarily need to be provided with a separate gas flow guide assembly. Instead, emission can be achieved by providing the emission port on an existing component (such as the sidewall 103). This approach increases the utilization of components, simplifies the assembly, and does not take up additional space in the reaction chamber 100. The present disclosure does not impose any restrictions on the arrangement of the emission port.

Further, the apparatus also includes a heating apparatus (not shown in the figure) that provides thermal energy for the reaction. The heating apparatus may be arranged on the wafer carrier 111 or attached to the sidewall 103. During the process, the heating apparatus heats the wafer to a required process temperature, enabling the precursor gas and reactive gases supplied to the wafer surface to react and form a thin film deposited on the wafer surface. In one embodiment, a deposited thin film material may be one or more of titanium nitride, gallium arsenide, gallium nitride, or aluminum gallium nitride.

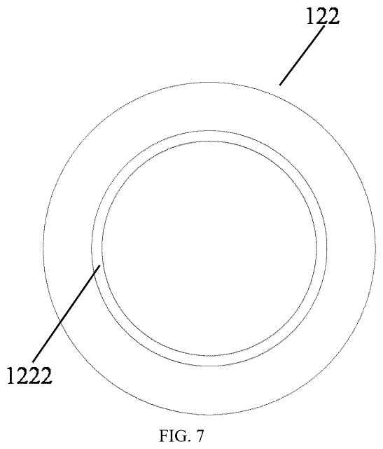

As mentioned above, in the process of thin film deposition, it is crucial to quickly and uniformly deliver the process gases to the surface of the wafer. Based on this, as shown in FIGS. 2 to 7, the gas delivery apparatus 120 of the present disclosure includes: a cover plate 121, a gas distributor 122, and a shower head 123. The gas distributor 122 includes a first surface and a second surface arranged opposite to each other, a gas diffusion channel 1221 is arranged in the gas distributor 122, the gas diffusion channel 1221 includes a recessed portion 1222 with a bottom surface protruding from the second surface, the recessed portion 1222 divides an area below the second surface into an inner area and an outer area, the recessed portion 1222 includes a first sidewall 1223 and a second sidewall 1224, where the first sidewall 1223 surrounds the inner area and includes a plurality of first gas channels 1225, and the second sidewall 1224 surrounds the first sidewall 1223 and includes a plurality of second gas channels 1226, and gases in the gas diffusion channel 1221 enter the inner area via the first gas channels 1225 and enter the outer area via the second gas channels 1226.

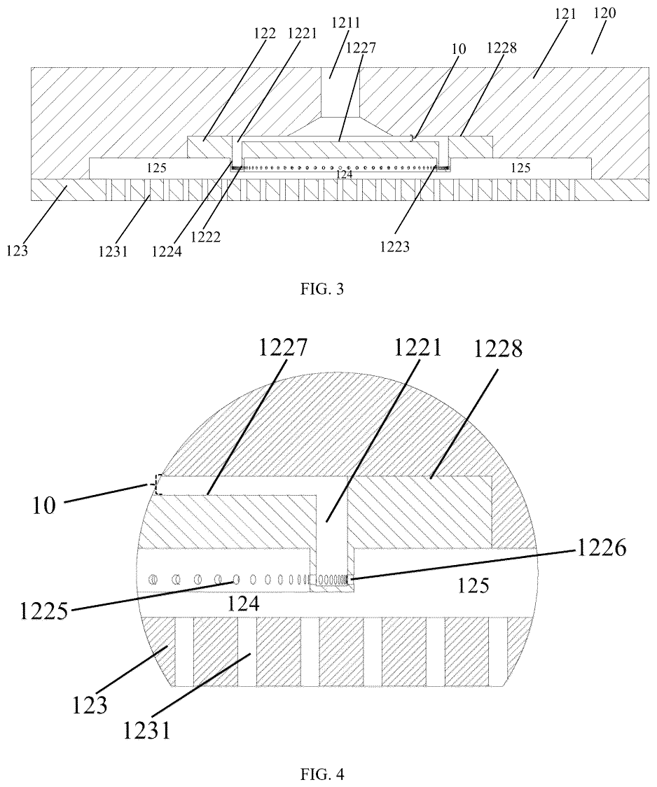

As shown in FIG. 2 and FIG. 3, the cover plate 121 is provided with a gas delivery channel 1211, the gas distributor 122 is located below the cover plate 121, and the gas delivery channel 1211 of the cover plate 121 is in gas communication with the gas diffusion channel 1221; and the shower head 123 is located below the gas distributor 122, and the shower head 123 is provided with a plurality of gas through-holes 1231. There is a gap between the gas distributor 122 and the shower head 123. An upper surface of the shower head 123 and the inner area below the gas distributor 122 form a central gas diffusion area 124, the upper surface of the shower head 123 and the outer area below the gas distributor 122 form a peripheral gas diffusion area 125, and gases in both the central gas diffusion area 124 and the peripheral gas diffusion area 125 flow out through the gas through-holes 1231 on the shower head 123 below.

During the process, the process gases of the gas supply apparatus flow into the gas diffusion channel 1221 of the gas distributor 122 via the gas delivery channel 1211 of the cover plate 121 and then flow into an accommodating space formed by the central gas diffusion area 124 and the peripheral gas diffusion area 125 via the first gas channels 1225 and the second gas channels 1226, respectively, and subsequently, the process gases are delivered from the accommodating space through the gas through-holes 1231 in the shower head 123 into the reaction chamber 100. The gas distributor 122 utilizes the principles of convection and diffusion to rapidly deliver the process gases from the gas diffusion channel 1221 into the accommodating space formed by the central gas diffusion area 124 and the peripheral gas diffusion area 125. Even if the process gases delivered from the gas delivery channel 1211 are at a high flow rate, they can be smoothly and rapidly delivered. This allows the process gases to diffuse evenly and rapidly within the accommodating space in a short period of time, resulting in a balanced distribution of process gases at various locations within the accommodating space. As a result, the evenly distributed process gases are delivered into the reaction chamber 100 through the shower head 123, resulting in a more uniform distribution of the process gases on the wafer surface, ensuring the quality of the thin film deposition on the wafer and improving the yield of wafer production. Additionally, the process gases are delivered into the reaction chamber 100 through the gas distributor 122 and the shower head, maintaining a high flow rate during the delivery process. This increases the throughput of the process gases in a short period of time while ensuring the uniform distribution of the process gases, which helps improve the yield of wafer production. On the other hand, a gap is provided between the gas distributor 122 and the shower head 123, allowing the process gases within the central gas diffusion area 124 and the peripheral gas diffusion area 125 to circulate freely. This prevents the formation of particles that could cause contamination of an environment within the chamber body and the wafer surface.

The gas distributor 122 of the present disclosure uses the gas diffusion channel 1221 to distribute the gases delivered from the gas delivery channel 1211 between the central gas diffusion area 124 and the peripheral gas diffusion area 125, ensuring uniformity in flow resistance in a radial direction. On the one hand, this solves the problem of uneven gas concentration distribution between a central area and a peripheral area in the prior art. On the other hand, the first gas channels 1225 and the second gas channels 1226 supply gases to the corresponding gas diffusion areas simultaneously, maintaining uniform gas pressure distribution in the central gas diffusion area 124 and the peripheral gas diffusion area 125 during rapid gas replacement, thereby achieving the goal of fast and uniform gas delivery.

In this embodiment, the top cover 101 and the cover plate 121 are integrally formed, reducing processing and assembly difficulty, and improving overall assembly efficiency. Of course, depending on actual requirements, the top cover 101 and the cover plate 121 may also be processed separately and then assembled. The present disclosure does not impose any restrictions on an assembly method thereof. Further, in this embodiment, a bottom of the gas delivery channel 1211 is a cone frustum opening structure, and the circumference of an inner sidewall of the cone frustum opening structure increases from top to bottom, meaning the circumference at the top of the inner sidewall thereof is smaller than that at the bottom. The closer the gas delivery channel 1211 is to the gas diffusion channel 1221, the larger a diffusion area of the process gases, making it easier to deliver the process gases into the gas diffusion channel 1221. When the flow rate of the process gases is high, the process gases can quickly diffuse into the gas diffusion channel 1221, ensuring the throughput of the process gases. Of course, the shape and structure of the gas delivery channel 1211 are not limited to the above description, and can also be configured as other structural types. The present disclosure does not impose any restrictions in this regard.

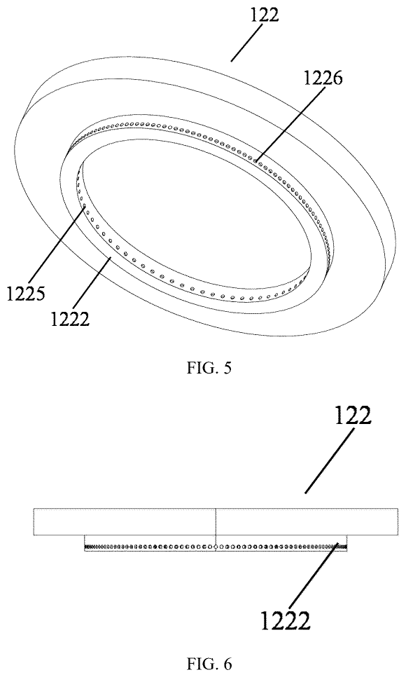

In one embodiment, the gas diffusion channel 1221 of the gas distributor 122 is an annular gas diffusion channel 1221 formed on the gas distributor 122, and the annular gas diffusion channel 1221 divides the first surface into a first central area surface 1227 and a first peripheral area surface 1228 (see FIG. 2). In this embodiment, the recessed portion 1222 of the gas distributor 122 is a continuous annular recessed structure (see FIG. 5), and correspondingly, the annular gas diffusion channel 1221 is a continuous annular gas channel. Preferably, the gas delivery channel 1211 is positioned at the central axis of the first central area surface 1227, and the process gases delivered from the gas delivery channel 1211 are rapidly and uniformly distributed in a circumferential direction within the annular gas diffusion channel 1221. It can be understood that in other embodiments, the annular gas diffusion channel 1221 may be composed of a plurality of discontinuous arc-shaped segment channels, which are distributed circumferentially to achieve radial area gas control. Further, the first sidewall 1223 and the second sidewall 1224 of the recessed portion 1222 of the annular gas diffusion channel 1221 may be of planar structures, stepped structures, or other structures. The present disclosure imposes no restrictions in this regard. In this embodiment, the first sidewall 1223 and the second sidewall 1224 are both vertical cylindrical structures, and a cross-section of the annular gas distribution channel 1221 is rectangular (in other embodiments, the cross-section may also be square). In another embodiment, the first sidewall 1223 and the second sidewall 1224 are both stepped structures, resulting in an inverted-T-shaped structure for the cross-section of the annular gas diffusion channel 1221. That is, a process gas inlet range of the annular gas diffusion channel 1221 is smaller than the range of the bottom thereof. A double-sided perforation structure/channel of the inverted-T-shaped structure of the gas distributor 122 can ensure uniformity in the circumferential direction while providing a sufficient cross-sectional area for local gas flow, thus avoiding blockages and allowing for a large throughput of process gases in a short time. This improves the diffusion efficiency of the process gases in the annular gas diffusion channel 1221 and expands a process window. This further ensures that the process gases output from the annular gas diffusion channel 1221 has a more uniform distribution in all directions, thereby making the distribution of the process gases delivered into the wafer surface more uniform. It can be understood that in another embodiment, the gas diffusion channel 1221 may be in communication with the gas delivery channel 1211 through one or more gas holes, thereby achieving the delivery of the process gases.

As shown in FIG. 2 and FIG. 3, in this embodiment, the height of the first central area surface 1227 is lower than the height of the first peripheral area surface 1228, so that the process gases maintain a required flow rate when flowing from the gas delivery channel 1211 into the gas diffusion channel 1221. Of course, the relative heights of the first central area surface 1227 and the first peripheral area surface 1228 are not limited to the above description. The height of the first central area surface 1227 may also be equal to or higher than the height of the first peripheral area surface 1228. The present disclosure does not impose restrictions in this regard. As an example, in another embodiment, the height of the first central area surface 1227 is the same as the height of the first peripheral area surface 1228, and a bottom side of the cone frustum opening structure of the gas delivery channel 1211 extends to a top opening of the gas diffusion channel 1221, delivering the process gases to the gas diffusion channel 1221. In another embodiment, the height of the first central area surface 1227 is higher than the height of the first peripheral area surface 1228. In this embodiment, a plurality of gas delivery channels 1211 can be arranged above the first peripheral area surface 1228 to deliver the process gas to the gas diffusion channel 1221.

As shown in FIG. 2 and FIG. 3, in this embodiment, the bottom of the cover plate 121 includes an annular two-step structure, and an outer edge of the gas distributor 122 is an annular structure; the circumference of a sidewall of a first step of the two-step structure of the cover plate 121 is smaller than the circumference of a sidewall of a second step, a horizontal surface of the first step makes contact with the first peripheral area surface 1228, a first gap 10 is formed between the first central area surface 1227 and the horizontal surface of the first step, and the gases are delivered via the gas delivery channel 1211 to the gas diffusion channel 1221 within the first gap 10. A bottom surface of the cover plate 121 is connected to the shower head 123. In one embodiment, the distance of the first gap 10 is greater than 1 mm, so that while achieving uniform distribution of the process gases, the process gases maintain a fast flow rate, thereby improving the throughput of process gases in the gas distributor 122. In one embodiment, the reaction gases include a first reaction gas and a second reaction gas, and in one circulation process, the time required for the first reaction gas, the purge gas, the second reaction gas and the purge gas is less than or equal to 2 s. Of course, a value range for this time is not limited to the above description. Depending on the process requirements and different gas flows, it can also fall within other time ranges.

Further, in this embodiment, the second surface located in the outer area is at the same height as the horizontal surface of the second step, i.e., a top surface of the peripheral gas diffusion area 125 is flat, so that the process gases delivered through the second gas channels 1226 can be quickly and uniformly distributed in the peripheral gas diffusion area 125, preventing localized turbulence during the diffusion of the process gases in the peripheral gas diffusion area 125. Of course, the height of a portion of the second surface that is located in the outer area may also differ from the height of the horizontal surface of the second step. The present disclosure imposes no restrictions in this regard.

It should be noted that the shape and structure of the cover plate 121 are not limited to the above description, and the connection method between the cover plate 121 and the gas distributor 122 is also not limited to the above, as long as rapid and uniform flow of the process gases can be achieved. The present disclosure does not impose any restrictions in this regard. As an example, in another embodiment, the bottom surface of the cover plate 121 is a planar structure, and when the height of the first central area surface 1227 is lower than the height of the first peripheral area surface 1228, the bottom surface of the cover plate 121 makes contact with the first peripheral area surface 1228, a first gap 10 is formed between the bottom surface of the cover plate 121 and the first central area surface 1227, and the gases are delivered via the gas delivery channel 1211 to the gas diffusion channel 1221 within the first gap 10. Further, a carrying member is provided between the cover plate 121 and the shower head 123. The carrying member is used to carry the gas distributor 122 (the carrying member, the shower head, or other components may extend to enclose the gas distributor 122 to prevent the process gases from diffusing outward beyond the peripheral gas diffusion area 125), so that the first gap 10 is formed between the bottom surface of the cover plate 121 and the first central area surface 1227, providing a space for the diffusion of the process gases, and allowing the process gases to flow into the gas diffusion channel 1221 at a required flow rate. It can be understood that the use of the carrying member is not affected by the shape and structure of the cover plate 121 and the gas distributor 122, and the carrying member is also applicable in other embodiments. Further, the position of the gas distributor 122 carried by the carrying member is adjustable, i.e., the distance of the first gap 10 formed between the bottom surface of the cover plate 121 and the first central area surface 1227 is adjustable, allowing the flow rate of the process gases delivered from the gas delivery channel 1211 to the gas diffusion channel 1221 to be adjustable, thereby enabling the gas distributor 122 to have different throughputs of the process gases to meet various process requirements. In one embodiment, in yet another embodiment, the bottom of the cover plate 121 includes an annular single-step structure, and an outer edge of the gas distributor 122 is an annular structure; a horizontal step surface of single-step structure makes contact with the first peripheral area surface 1228, and a first gap 10 is formed between the first central area surface 1227 and the horizontal surface of the step. The bottom surface of the cover plate 121 is connected to the shower head 123 to control the flow rate of the process gases.

In one embodiment, the cover plate 121 is connected to the gas distributor 122 through a mechanical fastening apparatus, and the shower head 123 is connected to the cover plate 121 through a mechanical fastening apparatus. As an example, the mechanical fastening apparatus is a bolt assembly. Of course, other connection methods may also be used between the cover plate 121 and the gas distributor 122 or between the cover plate 121 and the shower head 123. The present disclosure imposes no restrictions in this regard. Further, in this embodiment, materials for the preparation of the cover plate 121, the gas distributor 122 and the shower head 123 all include aluminum. In other embodiments, these components may also be prepared from other materials.

In the present disclosure, the gas distributor 122 and the cover plate 121 are connected in a detachable manner. Therefore, in practical applications, a plurality of gas distributors 122 of different specifications can be prepared for the thin film processing apparatus to meet the gas supply requirements of different processes. For example, gas distributors 122 with gas diffusion channels 1221 of different widths or gas distributors 122 with different distributions of the first gas channels 1225 and/or the second gas channels 1226 can be configured.

Further In one embodiment, the distance between an outer surface at a bottom of the recessed portion 1222 protruding from the second surface and the shower head 123 is greater than or equal to 1 mm, allowing the process gases between the central gas diffusion area 124 and the peripheral gas diffusion area 125 to flow into each other. This prevents the formation of particulate contaminants between the gas distributor 122 and the spray head 123, thus avoiding impurities in the process gases delivered to the reaction chamber 100 and ensuring the purity of thin film deposition.

In another embodiment, the distance between the recessed portion 1222 of the gas distributor 122 and the upper surface of the shower head 123 may be set to be greater than or equal to 0. When the distance between the recessed portion 1222 of the gas distributor 122 and the upper surface of the shower head 123 is equal to 0, the gas supply of the shower head 123 can be divided into central and peripheral areas to meet the requirement for partitioned gases into the reaction chamber 100.

As shown in FIG. 4, in this embodiment, both the first gas channels 1225 and the second gas channels 1226 are through holes in a horizontal direction. The process gases flowing into the gas diffusion channel 1221 are delivered horizontally to the central gas diffusion area 124 and the peripheral gas diffusion area 125, allowing the process gases to quickly and laterally diffuse within both the central gas diffusion area 124 and the peripheral gas diffusion area 125, thereby ensuring a more uniform distribution of the process gases in the accommodating space and avoiding excessive delivery to any localized area. Of course, the orientation of openings of the first gas channels 1225 and the second gas channels 1226 is not limited to the above. As an example, in other embodiments, the first gas channels 1225 and/or the second gas channels 1226 are through holes with an angle relative to the horizontal direction. The present disclosure does not impose restrictions on the orientation of the openings of the first gas channels 1225 and the second gas channels 1226, as long as the delivery of process gases can be achieved. Adjustments can be made based on actual requirements.

Further, the distance from the first sidewall 1223 of the recessed portion 1222 to the central axis of the gas distributor 122 is 10% to 80% of the radius of the gas distributor 122. In one embodiment, the distance from the first sidewall 1223 of the recessed portion 1222 to the central axis of the gas distributor 122 is 20% to 70% of the radius of the gas distributor 122. The distance from the first sidewall 1223 to the central axis of the gas distributor 122, combined with an appropriate width of the gas diffusion channel 1221, achieves more uniform gas distribution in the central gas diffusion area 124 and the peripheral gas diffusion area 125. The closer the first sidewall 1223 is to the central axis of the gas distributor 122, the faster the process gases from the gas delivery channel 1211 reach the recessed portion 1222 (gas diffusion channel 1221). This allows the process gases to quickly pass through the first gas channels 1225 and the second gas channels 1226 of the recessed portion 1222 and enter the central gas diffusion area 124 and the peripheral gas diffusion area 125, respectively. This further enables the process gases to quickly and evenly flow into the reaction chamber 100, ensuring uniform distribution of the process gases in a wafer processing area and guaranteeing a larger throughput of process gases, which helps improve wafer processing efficiency. On the other hand, when the distance between the first sidewall 1223 and the central axis of the gas distributor 122 becomes smaller, the area coverage (process gas capacity) of the central gas diffusion area 124 decreases, and the area coverage of the peripheral gas diffusion area 125 increases. Preferably, the process gas capacity of the central gas diffusion area 124 is the same as that of the peripheral gas diffusion area 125. This allows the process gases simultaneously entering the gas distributor 122 from the gas delivery channel 1211 to pass through the peripheral gas diffusion area 125 and the central gas diffusion area 124, and simultaneously enter the reaction chamber 100 through the gas channels of the shower head 123. This helps avoid interference from the previous gas to the current gas during the alternate supply of different types of process gases, further ensuring the purity and uniformity of the process gases in the reaction chamber 100.

In this embodiment, the installation height of the first gas channels 1225 is equal to that of the second gas channels 1226, the number of the first gas channels 1225 is equal to the number of the second gas channels 1226, and the diameter of the first gas channel 1225 is equal to the diameter of the second gas channel 1226, so as to facilitate the processing and preparation of the gas distributor 122. Preferably, the gas distributor 122 is integrally formed to avoid any impact on the delivery of the process gases during the multi-component assembly. It should be noted that the present disclosure does not impose restrictions on the relative position in height, number, or diameter of the first gas channels 1225 and the second gas channels 1226. The relative height, number, and diameter of both can be the same or different, and can be configured according to the specific requirements in actual applications. As can be seen from the above, due to the different positions of the recessed portion 1222, the capacity of the central gas diffusion area 124 and the peripheral gas diffusion area 125 may vary for the process gases. Furthermore, the first gas channels 1225 and the second gas channels 1226 can be adjusted to regulate the throughput rate of the process gases in different areas. As an example, in a certain process, it may be necessary for the peripheral gas diffusion area 125 to have a higher process gas throughput than the central gas diffusion area 124 to compensate for thin film deposition at an edge of the wafer. In such processes, the number of the second gas channels 1226 in the gas distributor 122 may be greater than the number of the first gas channels 1225, and/or the diameter of the second gas channels 1226 may be larger than that of the first gas channels 1225, so that more process gases enter the peripheral gas diffusion area 125 than the central gas diffusion area 124 within the same period of time. On the other hand, the relative height positions of the first gas channels 1225 and the second gas channels 1226 can be adjusted to cause slight variations in the throughput rate of the process gases in the central gas diffusion area 124 and the peripheral gas diffusion area 125, in order to meet process requirements or compensate for gas distribution imbalances caused by other factors.

As shown in FIG. 4 and FIG. 5, in this embodiment, a single layer of the first gas channels 1225 is provided on the first sidewall 1223, and a single layer of the second gas channels 1226 is provided on the second sidewall 1224. The distance from an outlet end of each first gas channel 1225 to the second surface is the same, and the distance from an outlet end of each second gas channel 1226 to the second surface is the same. It can be understood that the present disclosure does not impose restrictions on the number of layers of the gas channels. The number of layers can be configured according to actual requirements. For example, in other embodiments, at least two layers of the first gas channels 1225 may be provided on the first sidewall 1223, and/or at least two layers of the second gas channels 1226 may be provided on the second sidewall 1224, i.e., the distances from the outlet ends of at least two first gas channels 1225 to the second surface may not be the same, and/or the distances from the outlet ends of at least two second gas channels 1226 to the second surface may not be the same.

Further, in this embodiment, the plurality of first gas channels 1225 are uniformly arranged along a circumferential direction of the first sidewall 1223 of the recessed portion 1222, and the plurality of second gas channels 1226 are uniformly arranged along a circumferential direction of the second sidewall 1224 of the recessed portion 1222. The process gases inside the gas diffusion channel 1221 diffuse laterally along the circumferential direction in the central gas diffusion area 124 or the peripheral gas diffusion area 125 through the first gas channels 1225 or the second gas channels 1226, so as to quickly fill the central gas diffusion area 124 or the peripheral gas diffusion area 125. Of course, the plurality of first gas channels 1225 may also be non-uniformly arranged along the circumferential direction of the first sidewall 1223 of the recessed portion 1222. Similarly, the plurality of second gas channels 1226 may also be non-uniformly arranged along the circumferential direction of the second sidewall 1224 of the recessed portion 1222, in order to meet the varying input capacity requirements of process gases in different areas of the reaction chamber 100. The present disclosure imposes no restrictions in this regard.

In summary, in the gas distributor 122, the gas delivery apparatus 120, and the thin film processing apparatus of the present disclosure, the gas distributor 122 is provided with the gas diffusion channel 1221, and the gas diffusion channel 1221 includes the recessed portion 1222. The recessed portion 1222 includes the first gas channels 1225 and the second gas channels 1226 that deliver the process gases to different directions/areas. Based on the principles of convective flow and diffusion, the process gases delivered through the gas distributor 122 are more uniformly distributed, resulting in a more uniform distribution of the process gases delivered to the wafer surface. This ensures the quality of thin film deposition on the wafer and helps improve the yield rate of wafer production. At the same time, during the process of delivering the process gases through the gas distributor 122, a high flow rate can still be maintained, which not only ensures the uniform distribution of the process gases but also increases the throughput of the process gases in a short time, helping to improve the yield of wafer production.

The technical solution of the present disclosure solves the problem of limited throughput and insufficient uniformity of process gases in conventional gas delivery apparatuses, and can effectively ensure the step coverage rate of the thin film while meeting the production rate requirements.

In a process for growing TiN thin films using ALD technology, the gas delivery apparatus disclosed in the present disclosure can deliver process gases such as reaction gases such as TiCl₄ and NH₃ and purge gases such as N₂ uniformly and in large quantities into a process chamber body in less than 1 s, enabling rapid switching between different gases. Using the gas delivery apparatus disclosed in the present disclosure, a specific process gas can rapidly and uniformly fill the reaction chamber 100 in a short time, such as less than 0.25 s, with a maximum gas flow rate of up to 25000 sccm. In terms of gas distribution uniformity and throughput, it can simultaneously meet increasingly stringent process requirements.

Although the content of the present disclosure has been described in detail through the above preferred embodiments, it should be understood that the above description should not be considered as limitations to the present disclosure. Various modifications and alternatives to the present disclosure will become apparent to those skilled in the art upon reading the foregoing contents. Accordingly, the scope of protection of the present disclosure shall be limited by the appended claims.

1. A gas distributor, comprising:
a first surface and a second surface arranged opposite to each other, wherein a gas diffusion channel is arranged in the gas distributor, the gas diffusion channel comprises a recessed portion with a bottom surface protruding from the second surface, the recessed portion divides an area below the second surface into an inner area and an outer area, the recessed portion comprises a first sidewall and a second sidewall, where the first sidewall surrounds the inner area and comprises a plurality of first gas channels, and the second sidewall surrounds the first sidewall and comprises a plurality of second gas channels, and gases in the gas diffusion channel enter the inner area via the first gas channels and enter the outer area via the second gas channels.

2. The gas distributor according to claim 1, wherein the first gas channels are through holes in a horizontal direction or through holes at an angle to the horizontal direction.

3. The gas distributor according to claim 1, wherein the second gas channels are through holes in a horizontal direction or through holes at an angle to the horizontal direction.

4. The gas distributor according to claim 1, wherein a height of the first gas channels is same as or different from a height of the second gas channels.

5. The gas distributor according to claim 1, wherein a number of the second gas channels is equal to or not equal to a number of the first gas channels;
and/or, a diameter of the second gas channels is equal to or not equal to a diameter of the first gas channels.

6. The gas distributor according to claim 1, wherein the plurality of first gas channels are arranged uniformly or non-uniformly in a circumferential direction of the first sidewall of the recessed portion;
and/or, the plurality of second gas channels are arranged uniformly or non-uniformly in a circumferential direction of the second sidewall of the recessed portion.

7. The gas distributor according to claim 1, wherein distances from outlet ends of at least two of the first gas channels to the second surface are same or different;
and/or, distances from outlet ends of at least two of the second gas channels to the second surface are same or different.

8. A gas delivery apparatus, comprising:
a cover plate provided with a gas delivery channel;
a gas distributor located below the cover plate, the gas distributor comprising:
a first surface and a second surface arranged opposite to each other, wherein a gas diffusion channel is arranged in the gas distributor, the gas diffusion channel comprises a recessed portion with a bottom surface protruding from the second surface, the recessed portion divides an area below the second surface into an inner area and an outer area, the recessed portion comprises a first sidewall and a second sidewall, where the first sidewall surrounds the inner area and comprises a plurality of first gas channels, and the second sidewall surrounds the first sidewall and comprises a plurality of second gas channels, and gases in the gas diffusion channel enter the inner area via the first gas channels and enter the outer area via the second gas channels, wherein the gas delivery channel is in gas communication with the gas diffusion channel; and
a shower head, located below the gas distributor and provided with a plurality of gas through-holes;
wherein an upper surface of the shower head and the inner area below the gas distributor form a central gas diffusion area, and the upper surface of the shower head and the outer area below the gas distributor form a peripheral gas diffusion area, gases in both the central gas diffusion area and the peripheral gas diffusion area flow out through the gas through-holes on the shower head below.

9. The gas delivery apparatus according to claim 8, wherein the gas diffusion channel is an annular gas diffusion channel formed on the gas distributor, and the annular gas diffusion channel divides the first surface into a first central area surface and a first peripheral area surface.

10. The gas delivery apparatus according to claim 9, wherein the annular gas diffusion channel includes a continuous annular channel or a plurality of discontinuous arc-shaped segment channels.

11. The gas delivery apparatus according to claim 9, wherein a cross-section of the annular gas diffusion channel is at least one of square, rectangular, or inverted-T-shaped.

12. The gas delivery apparatus according to claim 9, wherein a height of the first central area surface is lower than a height of the first peripheral area surface.

13. The gas delivery apparatus according to claim 9, wherein a height of the first central area surface is equal to or higher than a height of the first peripheral area surface.

14. The gas delivery apparatus according to claim 8, a carrying member is provided between the cover plate and the shower head, and the carrying member is used to carry the gas distributor.

15. The gas delivery apparatus according to claim 14, wherein a position of the gas distributor carried by the carrying member is adjustable.

16. The gas delivery apparatus according to claim 9, wherein a bottom surface of the cover plate is a planar structure, and when a height of the first central area surface is lower than a height of the first peripheral area surface, the bottom surface of the cover plate makes contact with the first peripheral area surface, a first gap is formed between the bottom surface of the cover plate and the first central area surface, and the gases are delivered via the gas delivery channel to the gas diffusion channel within the first gap.

17. The gas delivery apparatus according to claim 9, wherein a bottom of the cover plate comprises a single-step structure, a horizontal step surface of the single-step structure makes contact with the first peripheral area surface, a first gap is formed between the horizontal step surface of the single-step structure and the first central area surface, and the gases are delivered via the gas delivery channel to the gas diffusion channel within the first gap.

18. The gas delivery apparatus according to claim 9, wherein a bottom of the cover plate comprises a two-step structure, a circumference of a sidewall of a first step of the two-step structure is smaller than a circumference of a sidewall of a second step, a horizontal surface of the first step makes contact with the first peripheral area surface, a first gap is formed between the horizontal surface of the first step and the first central area surface, and the gases are delivered via the gas delivery channel to the gas diffusion channel within the first gap.

19. The gas delivery apparatus according to claim 18, wherein a height of a portion of the second surface that is located in the outer area is same as or different from a height of the horizontal surface of the second step.

20. The gas delivery apparatus according to claim 18, wherein a distance of the first gap is greater than 1 mm.

21. The gas delivery apparatus according to claim 8, wherein a distance from the first sidewall of the recessed portion to a central axis of the gas distributor is 10% to 80% of a radius of the gas distributor.

22. The gas delivery apparatus according to claim 8, wherein a distance from the first sidewall of the recessed portion to a central axis of the gas distributor is 20% to 70% of a radius of the gas distributor.

23. The gas delivery apparatus according to claim 8, wherein a distance between the bottom surface of the recessed portion protruding from the second surface and the shower head is greater than or equal to 0.

24. The gas delivery apparatus according to claim 8, wherein a distance between the bottom surface of the recessed portion protruding from the second surface and the shower head is greater than or equal to 1 mm.

25. The gas delivery apparatus according to claim 8, wherein a bottom of the gas delivery channel is a cone frustum opening structure, and a circumference of an inner sidewall at a top of the cone frustum opening structure is smaller than a circumference of an inner sidewall at a bottom thereof.

26. The gas delivery apparatus according to claim 8, wherein the cover plate is connected to the gas distributor through a mechanical fastening apparatus;
and/or, the shower head is connected to the cover plate through a mechanical fastening apparatus.

27. The gas delivery apparatus according to claim 8, wherein materials for a preparation of the cover plate and/or the gas distributor and/or the shower head comprise aluminum.

28. A thin film processing apparatus, comprising:
a reaction chamber, comprising a top cover and a chamber body; and
a gas delivery apparatus connected to the top cover and used to deliver process gas into an interior of the reaction chamber, the gas delivery apparatus comprising:
a cover plate provided with a gas delivery channel;
a gas distributor located below the cover plate, the gas distributor comprising:
a first surface and a second surface arranged opposite to each other, wherein a gas diffusion channel is arranged in the gas distributor, the gas diffusion channel comprises a recessed portion with a bottom surface protruding from the second surface, the recessed portion divides an area below the second surface into an inner area and an outer area, the recessed portion comprises a first sidewall and a second sidewall, where the first sidewall surrounds the inner area and comprises a plurality of first gas channels, and the second sidewall surrounds the first sidewall and comprises a plurality of second gas channels, and gases in the gas diffusion channel enter the inner area via the first gas channels and enter the outer area via the second gas channels, wherein the gas delivery channel is in gas communication with the gas diffusion channel; and
a shower head, located below the gas distributor and provided with a plurality of gas through-holes;
wherein an upper surface of the shower head and the inner area below the gas distributor form a central gas diffusion area, and the upper surface of the shower head and the outer area below the gas distributor form a peripheral gas diffusion area, gases in both the central gas diffusion area and the peripheral gas diffusion area flow out through the gas through-holes on the shower head below.

29. The thin film processing apparatus according to claim 28, wherein the gas delivery apparatus is used to alternately deliver reaction gas and purge gas into an interior of the reaction chamber in a cyclic manner.

30. The thin film processing apparatus according to claim 29, wherein the reaction gas comprise a first reaction gas and a second reaction gas, and in one circulation process, a time required for the first reaction gas, the purge gas, the second reaction gas and the purge gas is less than or equal to 2 s.

31. The thin film processing apparatus according to claim 28, wherein the thin film processing apparatus is an atomic layer deposition process apparatus.

32. The thin film processing apparatus according to claim 28, wherein the top cover and the cover plate are integrally formed.

33. The thin film processing apparatus according to claim 28, wherein the gas distributor is detachably connected to the top cover.

34. The gas delivery apparatus according to claim 16, wherein a distance of the first gap is greater than 1 mm.

35. The gas delivery apparatus according to claim 17, wherein a distance of the first gap is greater than 1 mm.
